(19) United States
(12) Patent Application Publication
(10) Pub. No.: US 2005/0023448 A1
(43) Pub. Date: Feb. 3, 2005

(54) Position-detecting device

(76) Inventors: Yoshiaki Ogawara, Tokyo (JP); Hidemi Takakuwa, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/871,019

(22) Filed: Jun. 21, 2004

(30) Foreign Application Priority Data
Jun. 30, 2003 (JP) P2003-188924

(51) Int. Cl. H01L 31/00; G06M 7/00

(52) U.S. Cl. 250/221

(57) ABSTRACT

A liquid crystal display is provided with a detection range on its screen. Along right and left sides of this detection range, two mirrors are arranged as opposed to each other, and along one of sides perpendicular to the sides along which the mirrors are arranged a camera unit is arranged. The camera unit comprises a linear light sensor and a pinhole. When an arbitrary position in the detection range is pointed by a fescue, the linear light sensor detects a real image of a detection target. The linear light sensor also detects a mapped image of the detection target reflected by the mirror. Then, positional information of the real image and the mapped image of the detection target on the linear light sensor is used to obtain a two-dimensional position of the fescue in the detection range.

### BACKGROUND OF THE INVENTION

1. Field of the Invention

The present invention relates to a position-detecting device for detecting a position of a detection target. More specifically, it relates to a position-detecting device such as a touch panel.

2. Description of Related Art

The position-detecting device such as a touch panel for obtaining two-dimensional coordinates of the position touched by a finger, pen, etc. has conventionally been proposed, in order to accomplish processing due to the touched position on a screen of a display with the finger, pen or the like. As the position-detecting device, a resistor type touch panel is widely used which employs a transparent sheet on which electrodes are arrayed in a lattice to obtain coordinates of a touched location from its change in their resistance value.

However, such a resistor type touch panel has poor durability. Further, since the resistor type touch panel is superposed on a display, a quality of an image on the display is deteriorated, and furthermore, it is difficult to miniaturize the device because it becomes thick.

Further, an optical touch panel has been also proposed which generates a lattice of beams using a plurality of luminous bodies and optical sensors so that coordinates of any one of the beams may be obtained with or without being blocked.

Such an optical touch panel, however, is expensive because very many luminous bodies and optical sensors are necessary in order to improve accuracy of position detection. Also, the luminous bodies and the optical sensors are arrayed along vertical and horizontal sides of the display, so that it is difficult to miniaturize the device.

Furthermore, a technology has been proposed to obtain coordinates based on the triangulation principle using two cameras. However, such a technology using two cameras is also expensive.

### SUMMARY OF THE INVENTION

To solve these problems the present invention has been developed, and it is an object of the present invention to provide a small and inexpensive position-detecting device.

According to the present invention, the foregoing object is attained by a position-detecting device comprising a reflector and a detector having a detection surface for picking up a real image of a detection target and a mapped image of the detection target reflected by the reflector. The detector detects positional information of these real image and mapped image of the detection target on this detection surface. In the position-detecting device, coordinates of a position of the detection target are obtained from the positional information of the real image and the mapped image of the detection target on the detection surface.

In the position-detecting device related to the present invention, the detector picks up a real image of a detection target using the detection surface to detect positional information of the real image of the detection target on the detection surface. Further, the detector picks up a mapped image of the detection target reflected by the reflector using the detection surface, to thereby detect positional information of the mapped image of the detection target on the detection surface. In accordance with a position of the detection target, positions of the real image and the mapped image, which are picked up on the detection surface, change. Thus, position coordinates of the detection target can be obtained uniquely from the positional information of the real image and the mapped image of the detection target on the detection surface.

It is thus possible to detect a position of the detection target using one detector, thereby miniaturizing the device. Further, the device can be provided inexpensively. Furthermore, a position of the detection target is obtained optically and, therefore, can be obtained with high accurately.

The concluding portion of this specification particularly points out and directly claims the subject matter of the present invention. However those skill in the art will best understand both the organization and method of operation of the invention, together with further advantages and objects thereof, by reading the remaining portions of the specification in view of the accompanying drawing(s) wherein like reference characters refer to like elements.

### BRIEF DESCRIPTION OF THE DRAWINGS

FIGS. 1A and 1B are explanatory diagrams each for showing a configuration of a first embodiment of a position-detecting device according to the invention;

FIG. 2 is an explanatory diagram for showing a principle of measuring a two-dimensional position;

FIG. 3 is an explanatory diagram for showing an example of detecting a detection target;

FIG. 4 is a block diagram for showing a configuration of a control system of the position-detecting device;

FIGS. 5A and 5B are explanatory diagrams each for showing a variant of the first embodiment of the position-detecting device according to the invention;

FIG. 6 is an explanatory diagram for showing another variant of the first embodiment of the position-detecting device according to the invention;

FIG. 7 is an explanatory diagram for showing a relationship between a viewing field angle and a detection range of a camera unit;

FIGS. 8A-8C are explanatory diagrams each for showing a configuration of a second embodiment of a position-detecting device according to the invention;

FIGS. 9A and 9B are explanatory diagrams each for showing a variant of the second embodiment of the position-detecting device according to the invention;

FIGS. 10A and 10B are explanatory diagrams each for showing a configuration of a third embodiment of a position-detecting device according to the invention;

FIGS. 11A and 11B are explanatory diagrams each for showing a variant of the third embodiment of the position-detecting device according to the invention;

FIGS. 12A and 12B are explanatory diagrams each for showing another variant of the third embodiment of the position-detecting device according to the invention;

FIG. 13 is an explanatory diagram for showing a fourth embodiment of a position-detecting device according to the invention and a measuring principle thereof;

FIG. 14 is an explanatory diagram for showing a relationship between a viewing field angle and a detection range;

FIG. 15 is an explanatory diagram for showing another relationship between the viewing field angle and the detection range;

FIG. 16 is an explanatory diagram for showing a configuration of a fifth embodiment of a position-detecting device according to the invention;

FIGS. 17A and 17B are explanatory diagrams each for showing a principle of measuring a three-dimensional position of a detection target;

FIGS. 18A and 18B are explanatory diagrams each for showing an application of the fifth embodiment of the position-detecting device according to the invention;

FIG. 19 is an explanatory diagram for showing an arrangement of a three-dimensional position detector;

FIGS. 20A and 20B are explanatory diagrams each for showing an example of an infrared light irradiation range;

FIG. 21 is an explanatory diagram for showing a principle of measuring a three-dimensional position using a three-dimensional position detector;

FIG. 22 is another explanatory diagram for showing the principle of measuring a three-dimensional position using the three-dimensional position detector; and

FIG. 23 is a block diagram for showing a configuration of a control system of the three-dimensional position detector.

### DESCRIPTION OF THE PREFERRED EMBODIMENTS

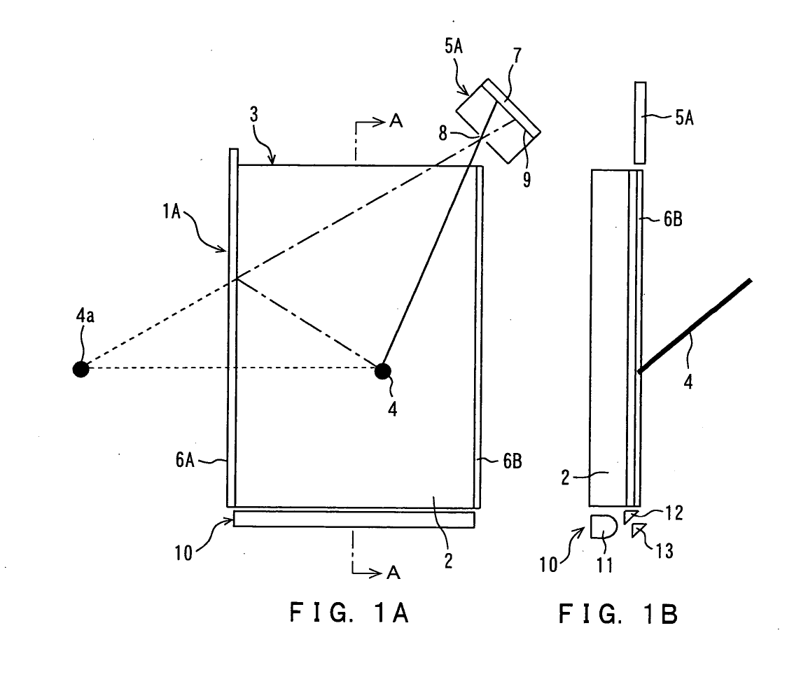

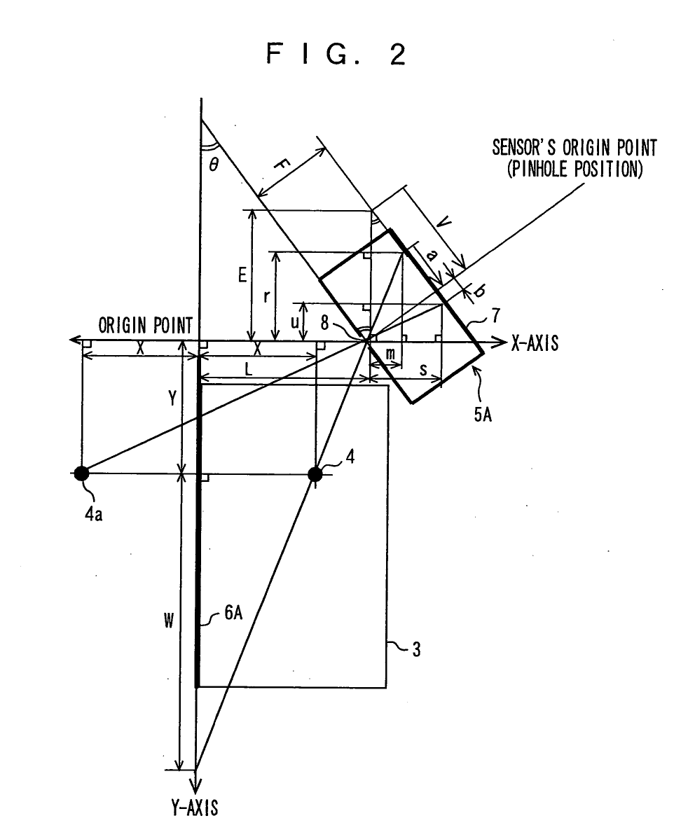

The following will describe embodiments of the present invention with reference to drawings. FIGS. 1A and 1B are explanatory diagrams for showing a configuration of a first embodiment of a position-detecting device according to the invention. FIG. 1A is a plan view thereof and FIG. 1B is a cross-sectional view thereof taken along line A-A of FIG. 1A. It is to be noted that hatching for indicating a cross-sectional view is not carried out to prevent the drawings from becoming too complicated.

The first embodiment of the position-detecting device 1A according to the invention is used to obtain a two-dimensional position of a detection target and utilized as, for example, a touch panel device. In the position-detecting device 1A, a planate detection range 3 is organized on a front face of a screen of a liquid crystal display 2, which is one example of a display. To obtain a position pointed by a fescue 4, which is one example of the detection target, in this detection range 3, a camera unit 5A and mirrors 6A, 6B are equipped.

The camera unit 5A is one example of detector and equipped with a linear light sensor 7 and has a pinhole 8 formed in it for focusing light to this linear light sensor 7. The linear light sensor 7 has a detection surface 9 on which a plurality of light-emitting elements, for example, photodiodes, is arrayed in a row. The pinhole 8 is arranged as opposed to the linear light sensor 7. It is to be noted that the camera unit 5A may use a lens besides a pinhole.

Each of the two mirrors 6A, 6B is one example of reflector and has a rod-like reflecting surface. The mirrors 6A, 6B are arranged along right and left sides of the rectangular detection range 3 respectively with their reflecting surfaces being opposed to each other. Further, the camera unit 5A is arranged along one side of the detection range 3 that is perpendicular to the sides along which the mirrors 6A, 6B are arranged. A light source unit 10 is arranged along the side opposite to the side along which the camera unit 5A is provided.

It is to be noted that the detection surface 9 of the linear light sensor 7 of the camera unit 5A is inclined by a predetermined angle with respect to a surface perpendicular to any one of the mirrors 6A, 6B. With this, the camera unit 5A is arranged as offset toward a side opposite to a mirror 6A that is opposed to the linear light sensor 7 in the detection range 3, that is, a side of the other mirror 6B. Further, the mirror 6A that is more remote from the camera unit 5A than the other mirror 6B is made longer than the other mirror 6B. Although a vertical length of the detection range 3 is set on the basis of a length of this other mirror 6B, preferably a length of the mirror 6A is larger than that of the detection range 3 in order to acquire a mapped image of the fescue 4 located at an arbitrary position in the detection range 3.

The light source unit 10 is one example of light source and provided as a front lamp for the liquid crystal display 2, which is a display of light-receiving type. The light source unit 10 comprises a prism 12, an optical wave-guide sheet, etc. for irradiating the screen of the liquid crystal display 2 with light from a lamp 11 such as a rod-like fluorescent tube. To utilize a portion of light from this lamp 11 in the position-detecting device 1A, a prism 13 is provided for turning light emitted from the lamp 11, toward the detection range 3. The lamp 11 and the prism 13 irradiate, in combination, the detection range 3 with the light from the side opposed to the side along which the camera unit 5A is provided. It is to be noted that if a self-luminous display given as display is used as light source in the position-detecting device 1A, such a configuration may be employed that a rod-like luminous area is provided at a portion of the display to irradiate the detection range 3 in combination with the prism.

In the position-detecting device 1A, the mirrors 6A, 6B, the linear light sensor 7, the pinhole 8, and the prism 13 that constitutes the light source unit 10 are arranged on the same plane as the detection range 3. It is to be noted that the reflecting surface of each of the mirrors 6A, 6B has a width of a few millimeters or less.

The following will describe operations of the position-detecting device 1A. The mirror 6A faces the detection surface 9 of the linear light sensor 7 to reflect light coming in a direction from the surface. Further, the light source unit 10 emits light in a direction of a surface of the detection range 3. When the fescue 4 points an arbitrary position in the detection range 3, a real image of the fescue 4 is picked up through an optical path indicated by a solid line in FIG. 1A. Further, a mapped image 4a of the fescue 4 is formed by the mirror 6A. The mapped image 4a of the fescue 4 is picked up through an optical path indicated by a dashed line in FIG. 1A. Accordingly, on the detection surface 9 of camera unit 5A, the real image of the fescue 4 and its mapped image 4a which is formed as reflected by the mirror 6A can be picked up in accordance with the position pointed in the detection range 3.

FIG. 2 is an explanatory diagram for showing a principle of measuring a two-dimensional position. It is to be noted that in a configuration shown in FIG. 2, the mirror 6A is arranged only along one side of the detection range 3. As two-dimensional coordinate axes of a position, the mirror 6A is supposed to be a Y-axis and an axis that is perpendicular to the mirror 6A and passes through the pinhole 8 is supposed to be an X-axis. Further, an intersection between the X-axis and the Y-axis is supposed to be an origin point.

The following parameters are necessary in operations.

<Fixed Values>

F: Distance between the linear light sensor 7 and the pinhole 8;
L: Distance between the mirror 6A and a center of the pinhole 8; and
θ: Angle between the detection surface 9 of the linear light sensor 7 and the mirror 6A
   <Variables>
a: Position of real image of fescue on linear light sensor 7 (origin point therefor is pinhole position);
b: Position of mapped image of fescue on linear light sensor 7 (origin point therefor is pinhole position);
Y: Vertical position of fescue as measured from origin point; and
X: Horizontal position of fescue as measured from origin point (distance from the mirror 6A).

In FIG. 2, following calculations are given:

$$cos θ = - V / E ∵ - V = E \times cos θ = F \times cos θ / sin θ$$

$$sin θF / E ∵ E = F / sin θ$$

$$m = ( - V + a ) \times sin θ = F \times cos θ + a \times sin θ$$

$$r = E - ( - V + a ) \times cos θ = F / sin θ - ( F \times cos θ / sin θ + a ) \times cos θ \\ = F / sin θ - F \times cos θ \times cos θ / sin θ - a \times cos θ$$

$$s = ( - V + b ) \times sin θ = ( F \times cos θ / sin θ + b ) \times sin θ \\ = F \times cos θ + b \times sin θ$$

$$u = E - ( - V + b ) \times cos θ = F / sin θ - ( F \times cos θ / sin θ + b ) \times cos θ \\ = F / sin θ - F \times cos θ \times cos θ / sin θ / sin θ - b \times cos θ$$

$$u / s = Y / ( L + X ) ∵ u \times ( L + X ) = s \times Y ∵ u \times L = - u \times X + s \times Y$$

$$r / m = ( W + Y ) / L , r / m = W / X ∵ r / m = ( X \times r / m + Y ) / L ∵ r \times L = r \times X + m \times Y$$

An equation of
−u×m×L=u×m×X−s×m×Y plus an equation of s×r×L=s×r×X+s×m×Y equals an equation of (s×r−u×m)×L=(u×m+s×r)×X. Thus, X=(s×r−u×m)×L/(s×r+u×m). X=L/2×F×(b−a)/{F×F×sin θ×cos θ+F×(a+b)×(½−cos θ×cos θ)−a×b×sin θ×cos θ} (1)

Similarly, an equation of
u×r×L=−u×r×X+s×r×Y plus an equation of u×r×L=u×r×X+u×m×Y equals an equation of 2×u×r×L=(s×r+u×m)×Y. Thus, Y=2×u×r×L/(s×r+u×m). Y=L×(F×sin θ−b×cos θ)×(F×sin θ−a×cos θ)/{F×F×sin θ×cos θ+F×(a+b)×(½−cos θ×cos θ)−a×b×sin θ×cos θ} (2)

Thus, a two-dimensional position (X, Y) of a subject to be photographed is obtained by the above equations (1) and (2) based on the above parameters.

As indicated by these Equations (1) and (2), a two-dimensional position (X, Y) of the fescue 4 can be obtained from physical fixed values F, L, and θ as well as positional information “a” of a real image and positional information “b” of a mapped image on the detection surface 9 of the linear light sensor 7.

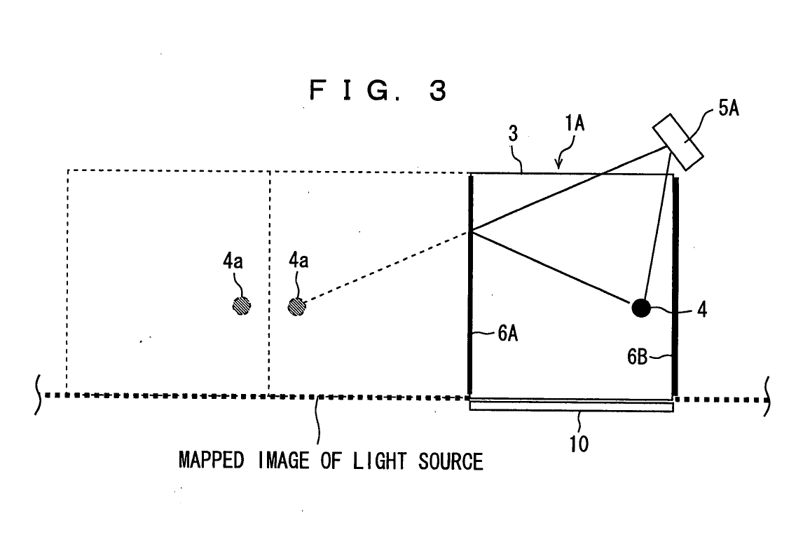

FIG. 3 is an explanatory diagram for showing an example of detecting a detection target (fescue 4) in a condition where the mirrors 6A, 6B are opposed to each other. In the position-detecting device 1A shown in FIG. 1, the mirrors 6A, 6B are arranged on the right and left sides of the detection range 3, respectively. Therefore, when the light source unit 10 is viewed from the linear light sensor 7, a mapped image due to rod-like emitted light extends infinitely in right and left horizontal directions. Accordingly, an image obtained through the rod-like emitted light blocked by a real image and a mapped image of the fescue 4 can be picked up by the linear light sensor 7 so that a two-dimensional position of the fescue 4 may be calculated on the basis of the principle described in FIG. 2. It is to be noted that although the mapped images 4a of the fescue 4 occur infinitely by effects of the mirrors 6A, 6B, thus opposed, two images of a subject are the real image and the mapped image of the fescue 4 which are near the origin point of the linear light sensor 7, so that by using these two positional information items, the two-dimensional position of the fescue 4 can be calculated.

FIG. 4 is a block diagram for showing a configuration of a control system of the position-detecting device. The position-detecting device 1A comprises a camera process block 15, a subject-selecting block 16, and a position-calculating block 17. The camera process block 15 controls the linear light sensor 7, shown in FIG. 1, in the camera unit 5A and performs A/D conversion processing, to output data of the picked up subject to the subject-selecting block 16.

The subject-selecting block 16 selects two items of subject data of the respective real image and mapped image of the fescue 4 from the picked-up subject data output from the camera process block 15. The position-calculating block 17 is one example of calculator and calculates a two-dimensional position of the fescue 4 based on the principle described in FIG. 2 from the items of positional information of the respective real image and the mapped image of the fescue 4 selected by the subject-selecting block 16. It is to be noted that positional data of the fescue 4 in the detection range 3 is sent to, for example, a personal computer (PC) 18 where an application related to the positional data of the fescue 4 is executed.

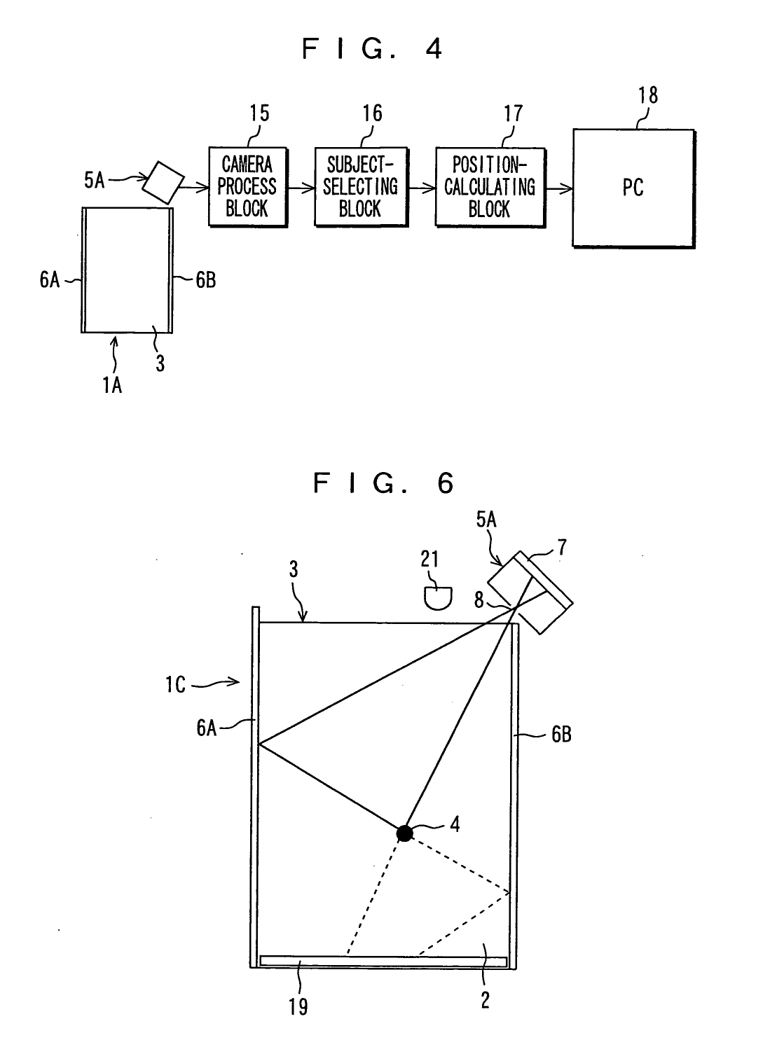

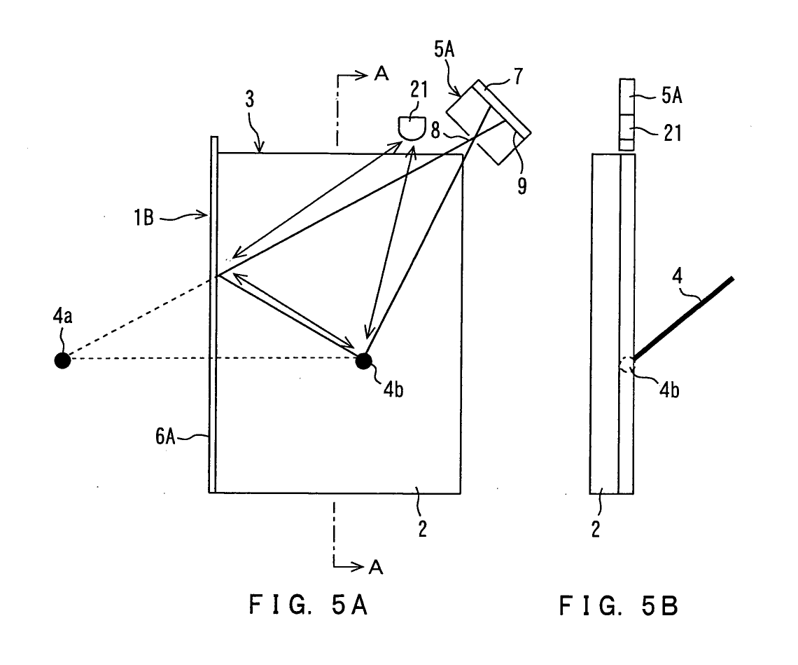

FIGS. 5A and 5B are explanatory diagrams each for showing a variant of the first embodiment of the position-detecting device according to the invention. FIG. 5A is a plan view thereof and FIG. 5B is a cross-sectional view thereof taken along line A-A of FIG. 5A. A position-detecting device 1B is used for obtaining a two-dimensional position of a detection target and utilized again as a touch panel device. The position-detecting device 1B comprises a planate detection range 3 on a front face of a screen of a liquid crystal display 2 and is provided with a mirror 6A only along one side of the detection range 3.

A camera unit 5A has such a configuration as described with reference to FIG. 1 and is provided with a linear light sensor 7 and a pinhole 8 for focusing light to this linear light sensor 7. This camera unit 5A is arranged on a side of the detection range 3, which is perpendicular to the side of the detection range 3 along which the mirror 6A is provided. The camera unit 5A is offset toward the side opposite to the mirrors 6A. Further, in the proximity of the pinhole 8, infrared luminous body 21 is arranged as light source. Furthermore, at a tip of a fescue 4, a retro-reflecting sphere 4b is provided as a reflecting structure. The retro-reflecting sphere 4b has a retro-reflecting function to reflect light with which it is irradiated, in an incident direction.

The following will describe operations of the position-detecting device 1B. The infrared light from the infrared luminous body 21 is radiated within a certain range of angle. A portion of the infrared light that is emitted directly toward the fescue 4 is reflected in the incident direction by the retro-reflecting function of the retro-reflecting sphere 4b at the tip of the fescue 4. This reflected light enters the linear light sensor 7 as a real image.

Another portion of the infrared light from the infrared luminous body 21 is reflected by the mirror 6A and impinges on the retro-reflecting sphere 4b at the tip of the fescue 4. This portion of infrared light is also reflected in the incident direction by the retro-reflecting function of the retro-reflecting sphere 4b and reflected again by the mirror 6A to go back toward the infrared luminous body 21. This reflected light enters the linear light sensor 7 as a mapped image.

It is thus possible to acquire, by the linear light sensor 7, positional information of the real image and the mapped image of the retro-reflecting sphere 4b of the fescue 4, thereby obtaining a two-dimensional position of the retro-reflecting sphere 4b based on the principle described in FIG. 2.

FIG. 6 is an explanatory diagram of another variant of the first embodiment of the position-detecting device according to the invention. A position-detecting device 1C shown in FIG. 6 comprises a planate detection range 3 on a front face of a screen of a liquid crystal display and is provided with mirrors 6A, 6B along each of the right and left sides of the detection range 3.

A camera unit 5A has such a configuration as described with reference to FIG. 1, thus comprising a linear light sensor 7 and a pinhole 8 for focusing light to this linear light sensor 7. This camera unit 5A is arranged as offset toward a side of the detection range 3 opposite to a mirror 6A that is opposed to the linear light sensor 7 in the detection range 3, that is, a side of the other mirror 6B. Further, in the proximity of the pinhole 8, an infrared luminous body is arranged. Furthermore, along the side of the detection range 3 opposed to the camera unit 5A and the infrared luminous body 21, a reflecting surface 19 is arranged. The reflecting surface 19 is one of a reflecting structure, thus comprising, for example, a retro-reflecting sphere arranged like a rod.

The following will describe operations of the position-detecting device 1C. Infrared light from the infrared luminous body 21 is radiated within a certain range of angle and a portion of the infrared light that is emitted directly toward the fescue 4 is reflected in an incident direction by a retro-reflecting function of the reflecting surface 19. This reflected light enters a linear light sensor 7 as a real image of fescue 4.

Another portion of the infrared light from the infrared luminous body 21 is reflected by the mirrors 6A, 6B and impinges on the reflecting surface 19. This portion of infrared light is reflected in an incident direction by the retro-reflecting function of the reflecting surface 19 and reflected again by the mirrors 6A, 6B to go back toward the infrared luminous body 21. This reflected light enters the linear light sensor 7 as a mapped image of the fescue 4. It is thus possible to acquire positional information of the real image and the mapped image of the fescue 4 by the linear light sensor 7, thereby obtaining a two-dimensional position of the fescue 4 based on the principle described in FIG. 2.

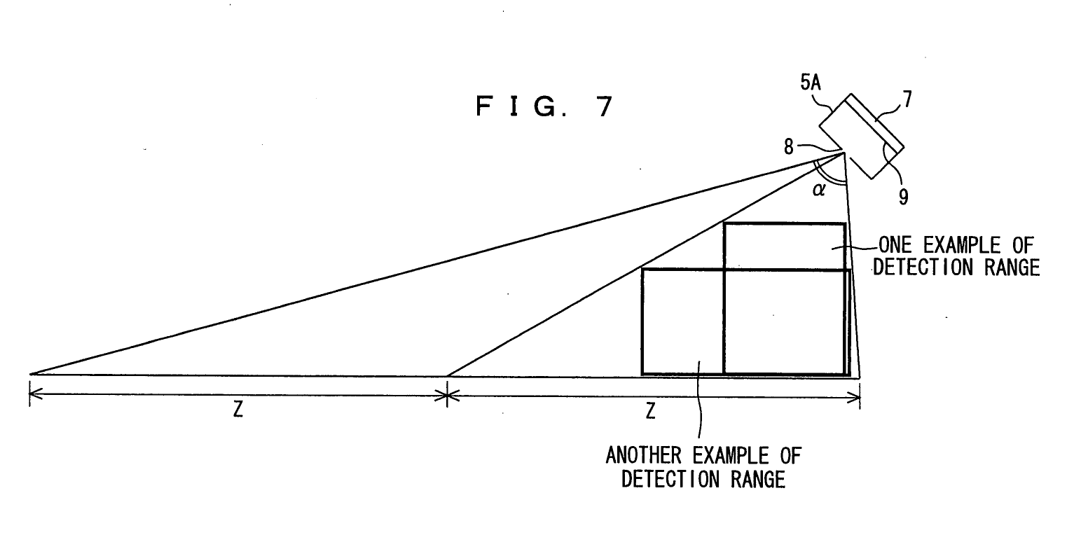

FIG. 7 is an explanatory diagram for showing a relationship between a viewing field angle and the detection range of the camera unit 5A. The camera unit 5A has a viewing field angle a regulated by a length of the detection surface 9 of the linear light sensor 7, a distance between this detection surface 9 and the pinhole 8, etc. Not only a real image of the fescue 4 but also its mapped image owing to the mirror(s) 6 need(s) to be present within this viewing field angle α, so that it is configured that a range that is twice the detection range 3 in size may be included in the viewing field angle a of the camera unit 5A. Accordingly, the detection range 3 may be a vertically long or horizontally long rectangle as shown in FIG. 7.

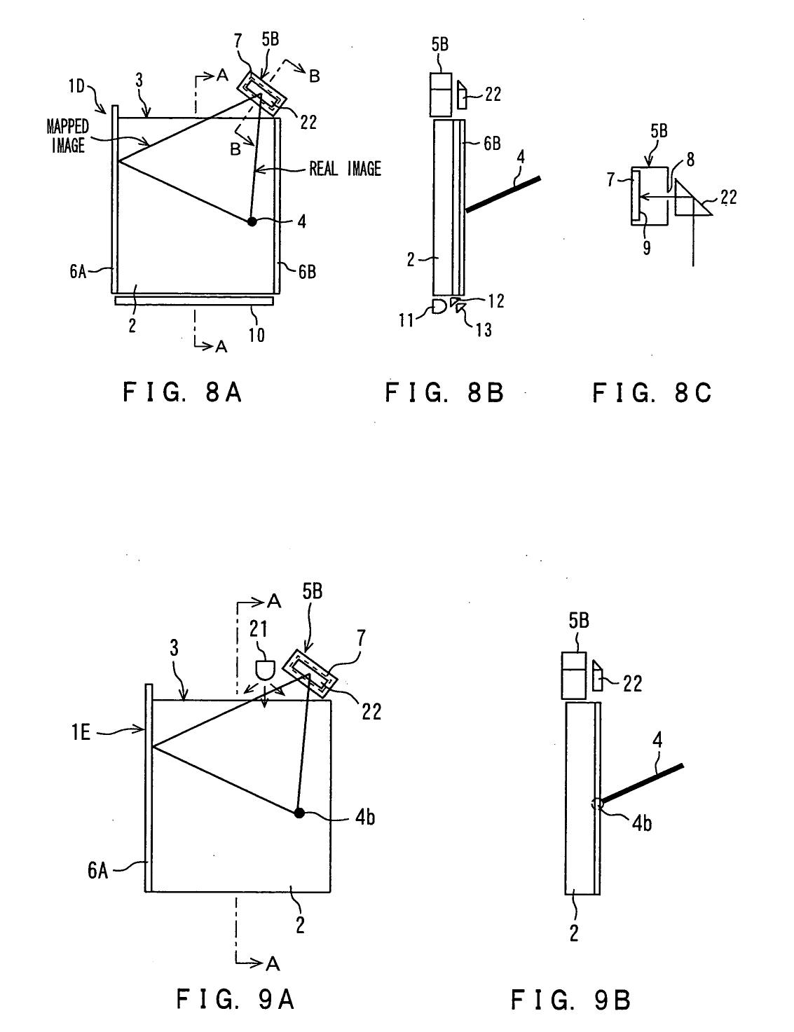

FIGS. 8A-8C are explanatory diagrams each for showing a configuration of a second embodiment of a position-detecting device according to the invention. FIG. 8A is a plan view thereof, FIG. 8B is a cross-sectional view thereof taken along line A-A of FIG. 8A, and FIG. 8C is a cross-sectional view thereof taken along line B-B of FIG. 8A. Such a position-detecting device 1D is used for obtaining a two-dimensional position of a detection target and utilized again as a touch panel device. In the position-detecting device 1D, a detection surface 9 of a linear light sensor 7 of a camera unit 5B is arranged in parallel with a plane of a detection surface 3. Further, to detect a real image and a mapped image of a fescue 4 in the detection range 3, a prism 22 is provided as optical path changing device.

The prism 22 is in the same plane as the detection range 3 and provided as opposed to a pinhole 8 formed in the camera unit 5B. Mirrors 6A, 6B and a light source unit 10 are of the same configurations as that of the first embodiment of the position-detecting device 1A.

The following will describe operations of the position-detecting device 1D. Light with which the fescue 4 is irradiated enters the prism 22 and, therefore, is turned toward the camera unit 5B, so that a real image and a mapped image of the fescue 4 are incident upon the linear light sensor 7 of the camera unit 5B. It is thus possible to calculate a two-dimensional position of the fescue 4 based on the principle described in FIG. 2.

In the above configuration, the camera unit 5B can be arranged below the surface of the detection range 3. Although the prism 22 is arranged in the same plane as the detection range 3, the prism 22 needs only to have a thickness equivalent to a width of, for example, the mirrors 6A, 6B so that projection on a display surface of a liquid crystal display 2 can be kept low.

FIGS. 9A and 9B are explanatory diagrams each for showing a variant of the second embodiment of the position-detecting device according to the invention. FIG. 9A is a plan view thereof and FIG. 9B is a cross-sectional view thereof taken along line A-A of FIG. 9A. Such a position-detecting device 1E has a configuration so that a prism 22 is provided as in the case of the second embodiment of the position-detecting device 1D described with reference to FIGS. 8A-8C, a camera unit 5B is mounted below a plane of a display, and an infrared luminous body 21 described with the position-detecting device 1B is used as a light source. The infrared luminous body 21 is arranged in the proximity of a plane of incidence of the prism 22. Further, a retro-reflecting sphere 4b is provided at a tip of a fescue 4. A mirror 6A is provided along only one of sides of a detection range 3.

The following will describe operations of the position-detecting device 1E. Infrared light from the infrared luminous body 21 is radiated within a certain range of angle and a portion of the infrared light that is emitted directly toward the fescue 4 is reflected in an incident direction by a retro-reflecting function of the retro-reflecting sphere 4b at the tip of the fescue 4. This reflected light enters the prism 22 and is turned in direction to enter a linear light sensor 7 as a real image.

Another portion of the infrared light from the infrared luminous body 21 is reflected by the mirror 6A and impinges on the retro-reflecting sphere 4b at the tip of the fescue 4. This portion of infrared light is reflected in an incident direction by the retro-reflecting function of the retro-reflecting sphere 4b and reflected again by the mirror 6A to go back toward the infrared luminous body 21. This reflected light enters the prism 22 and is turned in direction to enter the linear light sensor 7 as a mapped image.

It is thus possible to acquire positional information of the real image and the mapped image of the retro-reflecting sphere 4b of the fescue 4 by the linear light sensor 7, thereby obtaining a two-dimensional position of the retro-reflecting sphere 4b based on the principle described in FIG. 2.

As described above, also in a configuration where the infrared luminous body 21 is used as a light source, by using the prism 22 etc., the camera unit 5B can be arranged below the plane of the detection range 3, thereby keeping low a projection on a display surface of a liquid crystal display 2.

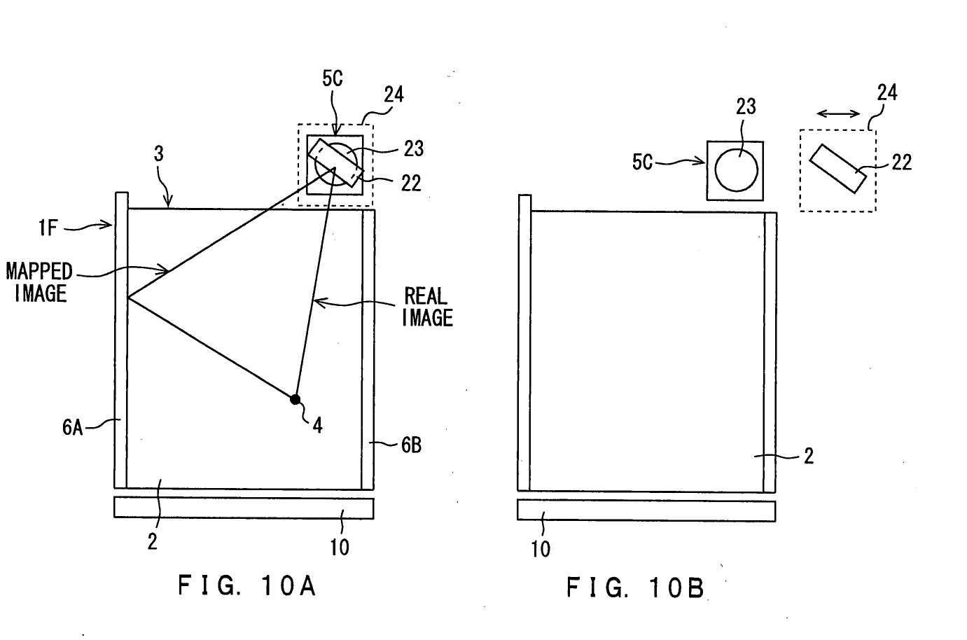

FIGS. 10A and 10B are explanatory diagrams each for showing a configuration of a third embodiment of a position-detecting device according to the invention. Such a position-detecting device 1F comprises, as detector, a camera unit 5C having a two-dimensional light sensor 23 such as a charge coupled device (CCD), which camera unit 5C is provided with a function to detect a position of a fescue 4 and an ordinary photographing function.

The position-detecting device 1F comprises a planate detection range 3 on a front face of a screen of a liquid crystal display 2. The 3 camera unit 5C comprises a two-dimensional light sensor 23 in which a plurality of image pick-up elements is arrayed two-dimensionally and a lens, not shown, in such a configuration that a detection surface 23a of the two-dimensional light sensor 23 is arranged in parallel with a surface of the detection range 3.

A prism 22 is provided which permits the camera unit 5C to detect a real image and a mapped image of the fescue 4 in the detection range 3, with a mechanism being provided for moving this prism 22. For example, an openable-and-closable cap portion 24 is provided in front of the camera unit 5C. This cap portion 24 constitutes moving device and can move between a position to close a front side of the camera unit 5C and a position to open it. On a back surface of this cap portion 24, the prism 22 is mounted.

The following will describe operations of the position-detecting device 1F. When the cap portion 24 is put on the unit to close it as shown in FIG. 10A, the prism 22 is located in front of the camera unit 5C. Therefore, when light with which the fescue 4 is irradiated enters the prism 22, the light is turned in direction toward the camera unit 5C, so that a real image and a mapped image of the fescue 4 are made incident upon the two-dimensional light sensor 23 of the camera unit 5C. Since a horizontal direction in the two-dimensional light sensor 23 is generally intended to be parallel with a rim of the liquid crystal display 2, light from the prism 22 forms an oblique straight line on the two-dimensional light sensor 23. From positional information of the real image and the mapped image of the fescue 4 on this straight line, a two-dimensional position of the fescue 4 can be obtained on the basis of the principle described in FIG. 2.

When the cap portion 24 is removed as shown in FIG. 10B, the prism 22 goes back from the camera unit 5C to open its front side. Then, ordinary photographing is possible by utilizing the camera unit 5C.

In the above configuration, the prism 22 can be retracted by providing the camera unit 5C with the two-dimensional light sensor 23, thereby utilizing the photographing camera also as position-detector.

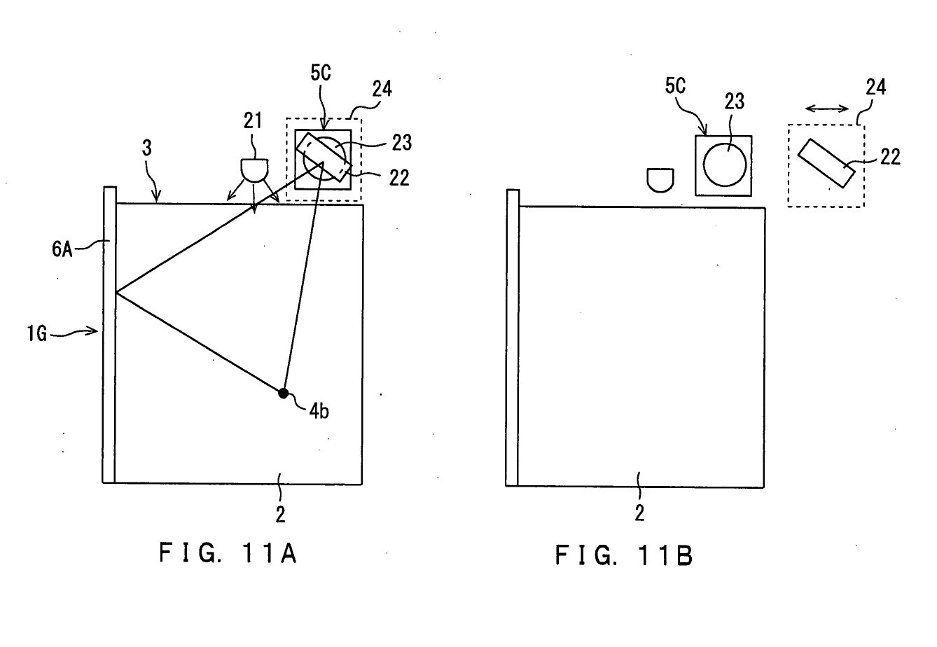

FIGS. 11A and 11B are explanatory diagrams each for showing a variant of the third embodiment of the position-detecting device according to the invention. Such a position-detecting device 1G has a configuration so that a movable prism 22 is provided as in the case of the third embodiment of the position-detecting device 1F described with reference to FIGS. 10A and 10B. In the position-detecting device 1G, a camera unit 5C performs ordinary photographing and detects a two-dimensional position of a fescue 4 and an infrared luminous body 21 described with the position-detecting device 1B is used as a light source.

Operations and effects of the position-detecting device 1G are the same as those of the position-detecting device 1E when the cap portion 24 is put on the unit to close it. When the cap portion 24 is removed, on the other hand, the operations and effects thereof are the same as those of the position-detecting device 1F.

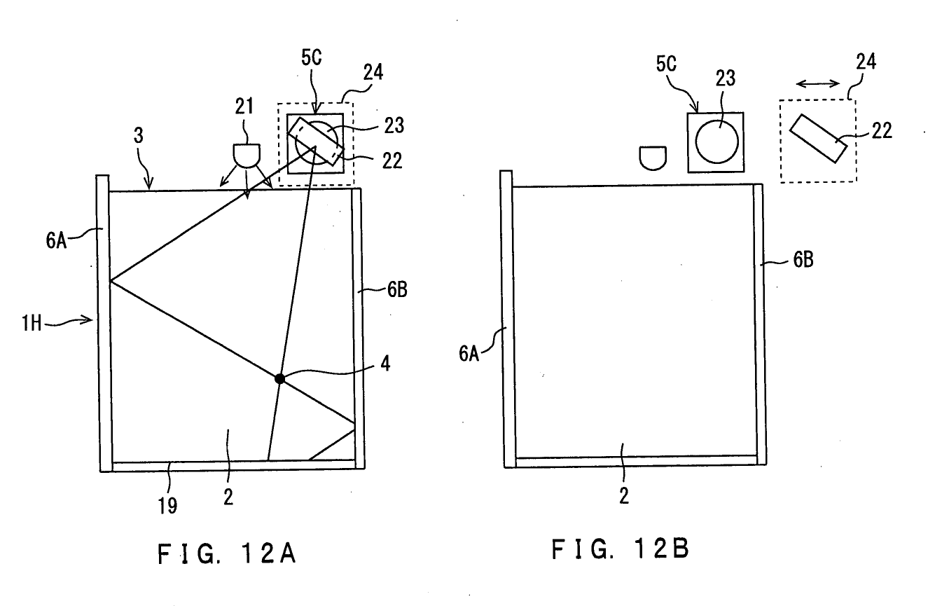

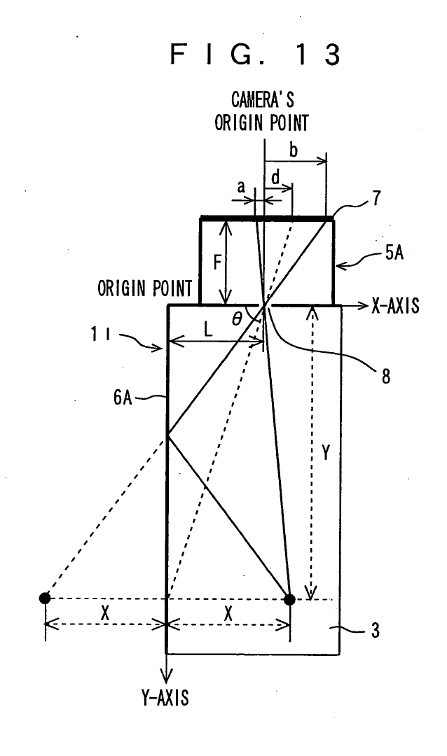

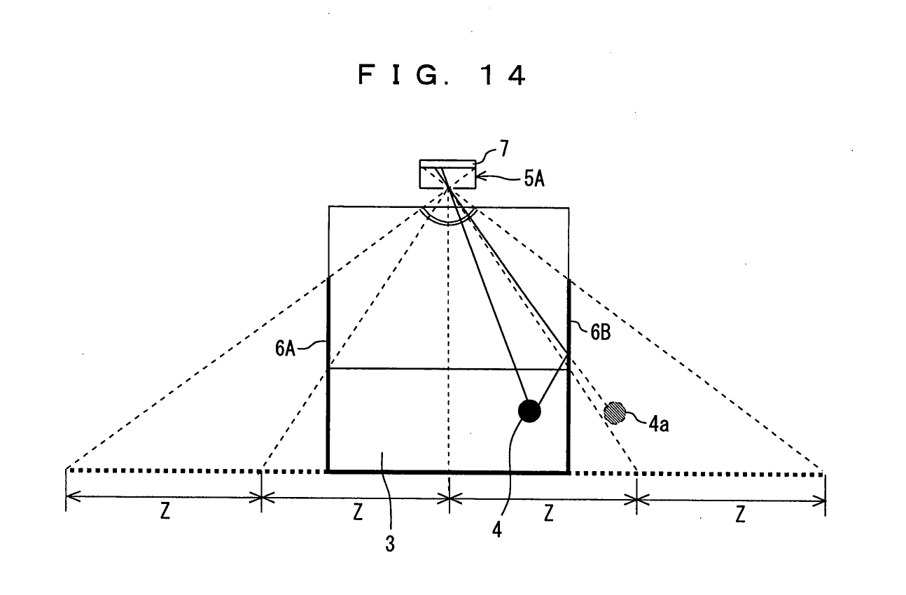

FIGS. 12A and 12B are explanatory diagrams each for showing another variant of the third embodiment of the position-detecting device according to the invention. Such a position-detecting device 1H has a configuration so that a movable prism 22 is provided as in the case of the third embodiment of the position-detecting device 1F described with reference to FIGS. 10A and 10B. In the position-detecting device 1H, a camera unit 5C performs ordinary photographing and detects a two-dimensional position of a fescue 4 and an infrared luminous body 21 described with the position-detecting device 1B is used as a light source. Further, a reflecting surface 19 is arranged as opposed to the infrared luminous body 21. The reflecting surface 19 is one example of a reflecting structure, thus comprising, for example, a retro-reflecting sphere arranged like a rod.

The following will describe operations of the position-detecting device 1H. When the cap portion 24 is put on the unit to close it as shown in FIG. 12A, the prism 22 is located in front of the camera unit 5C. Infrared light from the infrared luminous body 21 is radiated within a certain range of angle and a portion of the infrared light that is emitted directly toward the fescue 4 is reflected in an incident direction by a retro-reflecting function of the reflecting surface 19. This reflected light enters the prism 22 to be turned in direction and is made incident upon a two-dimensional light sensor 23 as a real image of the fescue 4.

Another portion of the infrared light from the infrared luminous body 21 is reflected by mirrors 6A, 6B and impinges on the reflecting surface 19. This portion of infrared light is reflected in an incident direction by the retro-reflecting function of the reflecting surface 19 and reflected again by the mirrors 6A, 6B to go back toward the infrared luminous body 21. This reflected light enters the prism 22 to be turned in direction and made incident upon the two-dimensional light sensor 23 as a mapped image of the fescue 4. It is thus possible to obtain a two-dimensional position of the fescue 4 based on the principle described in FIG. 2. It is to be noted that operations and effects of the position-detecting device 1H in a case where the cap portion 24 is removed are the same as those of the position-detecting device 1F.

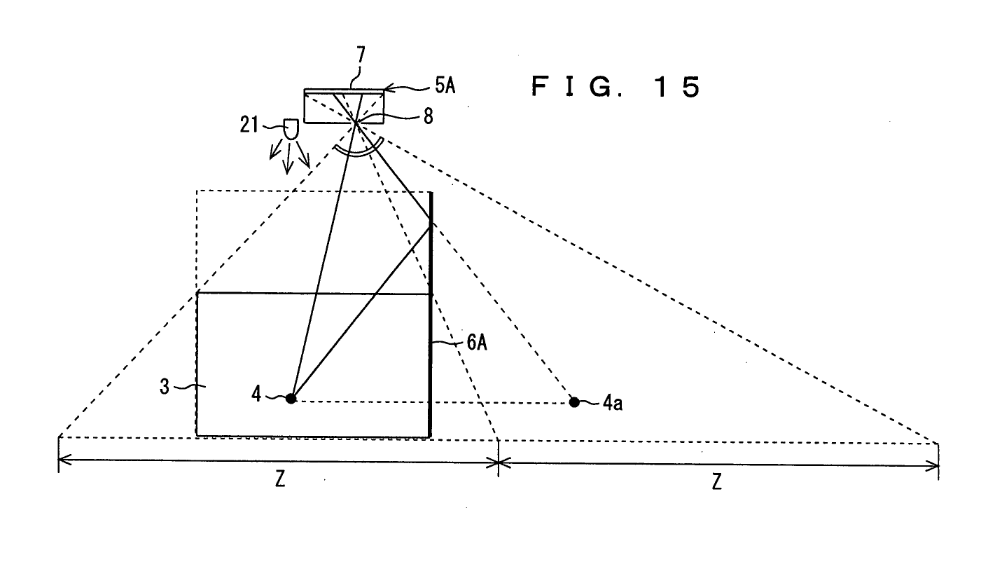

FIG. 13 is an explanatory diagram for showing a configuration of a fourth embodiment of a position-detecting device according to the invention and a measuring principle therefor. Such a position-detecting device 1I is equipped with a camera unit 5A in which a linear light sensor 7 serving as detector is perpendicular to a mirror 6A. This configuration can simplify positional calculation. The measuring principle therefor is described with reference to FIG. 13 as follows: the mirror 6A is supposed to have been arranged only along one side of a detection range 3 in configuration. As two-dimensional coordinate axes of a position, the mirror 6A is supposed to be a Y-axis and an axis that is perpendicular to the mirror 6A and passes through a pinhole 8 is supposed to be an X-axis. Further, an intersection between the X-axis and the Y-axis is supposed to be an origin point.

The following parameters are necessary in operations.

<Fixed Values>

F: Distance between the linear light sensor 7 and pinhole 8;
L: Distance between the mirror 6A and a center of the pinhole 8;
   <Variables>
a: Position of real image of fescue on the linear light sensor 7 (the origin point is pinhole position);
b: Position of mapped image of the fescue on the linear light sensor 7 (origin point is pinhole position);
Y: Vertical position of the fescue as measured from the origin point (distance from the pinhole 8);
X: Horizontal position of the fescue as measured from the origin point (distance from the mirror 6A).

In FIG. 13, following calculations are given:
(−a+b)/2=d−a ∵d=(a+b)/2
Tan θ=Y/L=F/d
X/Y =(b−a)/2×F

According to the calculation, a two-dimensional position (X, Y) of the fescue 4 is obtained by the following equations (3) and (4) based on the above parameters.
X=L×(b−a)/(a+b) (3)
Y=F×L/d=2×F×L/(a+b) (4)

As indicated by these Equations (3) and (4), a two-dimensional position (X, Y) of a subject can be obtained from physical fixed values F and L as well as positional information “a” of a real image and positional information “b” of a mapped image on a detection surface 9 of the linear light sensor 7. It is to be noted that Equations (3) and (4) are obtained by substituting θ=90° into Equations (1) and (2) respectively.

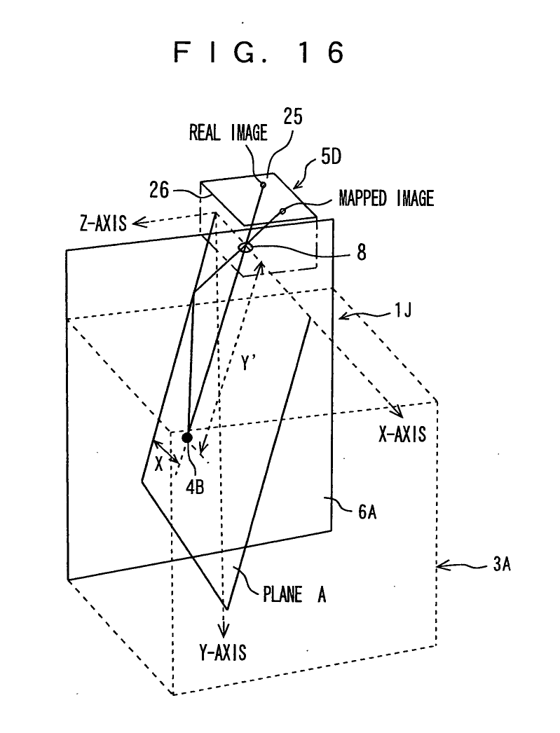

FIGS. 14 and 15 are explanatory diagrams each for showing a relationship between a viewing field angle and a detection range. If the mirror(s) 6 and the linear light sensor 7 of the camera unit 5A are configured to be perpendicular to each other, it is necessary to set a region which is roughly twice as large as the detection range 3 in a viewing field angle of the camera unit 5A.

In FIG. 14, the mirrors 6A, 6B are arranged along right and left sides of the detection range 3 and the camera unit 5A is arranged so that the pinhole 8 may be above a center of the detection range 3, thereby spreading the detection range 3 with respect to the viewing field angle.

It is figured out that in a configuration of FIG. 14, supposing a range of 4×Z can be set in the viewing field angle of the camera unit 5A, the detection range 3 can be spread to 2×Z.

In FIG. 15, the mirror 6A is arranged along one of the sides of the detection range 3 and the camera unit 5A is arranged so that the pinhole 8 may be offset from a center of the linear light sensor 7 toward the mirror 6A, thereby spreading the detection range 3 with respect to the viewing field angle. It is figured out that in a configuration of FIG. 15, supposing a range of 2×Z can be set in the viewing field angle of the camera unit 5A, the detection range 3 can be spread to 1×Z.

In the position-detecting device described above, by using the mirror(s) 6, a real image and a mapped image of a detection target can be detected with the one linear light sensor 7 or a two-dimensional light sensor 23 to thereby obtain a two-dimensional position of the detection target. It is thus possible to miniaturize the device. In a case where it is applied to a touch panel device, it is necessary to provide only the mirror (s) 6 along the side of a display, thereby increasing a degree of freedom in design. Further, the mirror (s) 6 can be reduced in width, to prevent the display from becoming thick.

Furthermore, using the linear light sensor 7 or the two-dimensional light sensor 23 allows the position of a detection target to be obtained with high accuracy. Further, since a sheet such as a resistor type touch panel is unnecessary, the device can have high durability and will not suffer from deterioration in picture quality of display.

FIG. 16 is an explanatory diagram for showing a configuration of a fifth embodiment of a position-detecting device according to the invention. Such a position-detecting device 1J is used to obtain a three-dimensional position of a detection target. The position-detecting device 1J comprises a quadratic prism-shaped detection range 3A. To obtain a three-dimensional position of a detection target 4B present in this detection range 3B, it comprises a camera unit 5D and a mirror 6A.

The camera unit 5D is one example of detector and comprises a two-dimensional light sensor 25 and a pinhole 8 for focusing light to this two-dimensional light sensor 25. The two-dimensional light sensor 25 has a detection surface 26 in which a plurality of image pick-up elements is arrayed two-dimensionally. The pinhole 8 is arranged as opposed to the two-dimensional sensor 25. It is to be noted that the camera unit 5D may use a lens besides a pinhole.

The mirror 6A has a planate reflecting surface. As opposed to this reflecting surface, the quadratic prism-shaped detection range 3A is formed. That is, the mirror 6A is arranged on one of faces of the detection range 3A. Further, on a face of the detection range 3A perpendicular to the face on which the mirror 6A is provided, the camera unit 5D is arranged. It is to be noted that the detection surface 26 of the two-dimensional light sensor 25 is made perpendicular to the mirror 6A.

The following will describe operations of the position-detecting device 1J. When the detection target 4B is present in the detection range 3A, a real image of this detection target 4B is picked up by the two-dimensional light sensor 25 of the camera unit 5D. Further, a mapped image of the detection target 4B reflected by the mirror 6A is picked up by the two-dimensional light sensor 25.

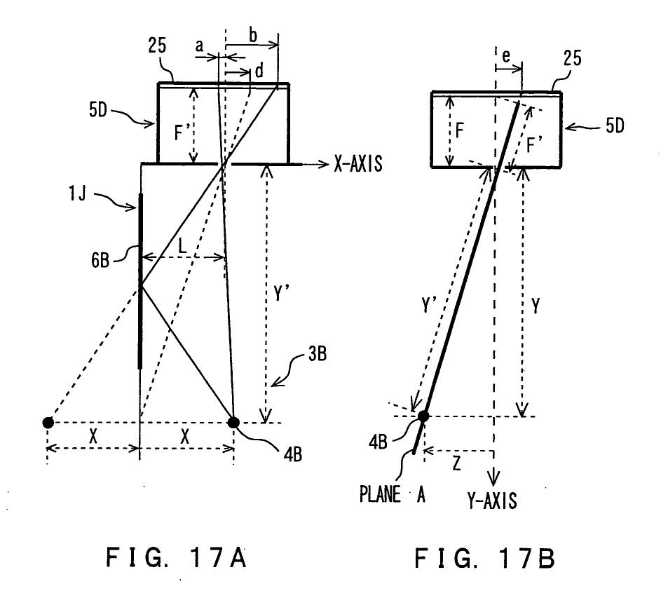

FIGS. 17A and 17B are explanatory diagram each for showing a principle of measuring a three-dimensional position of a detection target. FIG. 17A shows a principle of measuring it in a plane A, which is perpendicular to the mirror 6A and through which the detection target 4B and the pinhole 8 pass. FIG. 17B shows a principle of measuring it in a Z-Y projection plane and the plane A. In FIGS. 16, 17A and 17B, it is to be noted that an axis that is perpendicular to the mirror 6A and passes through the pinhole 8 is supposed to be an X-axis and a straight line that is perpendicular to the two-dimensional light sensor 25 and intersects with the X-axis on a mirror surface is supposed to be a Y-axis. Also, a straight line that is parallel with a plane including the two-dimensional light sensor 25 and a tangent line of the mirror surface and intersects with the X-axis on the mirror surface is supposed to be a Z-axis. Further, an intersection between the X-axis, the Y-axis, and the Z-axis is supposed to be an origin point.

First, in the plane A, a two-dimensional position of the detection target 4B is obtained. In operations, the following parameters are required.

<Fixed Values>

F: Distance between the two-dimensional light sensor 25 and the pinhole 8;
L: Distance between the mirror 6A and the pinhole 8;
   <Variables>
a: X-axial position of real image of detection target on the two-dimensional light sensor 25;
b: X-axial position of mapped image of the detection target on the two-dimensional light sensor 25;
Y: Vertical position of the detection target as measured from the origin point;
X: Horizontal position of the detection target as measured from the origin point (distance from the mirror 6A); and
Z: Depth position of the detection target as measured from the origin point.

In FIGS. 17A and 17B, following calculations are given:
Y′=F×L/d=2×F′×L/(a+b)
∵Y=2×F×L/(a+b)
(b−a)/(2×F′)=X/Y′
∵X=Y′×(b−a)/(2×F′)
∵X=Y×(b−a)/(2×F)
∵X=L×(b−a)/(a+b)

Thus, a two-dimensional position (X, Y) of the detection target 4B in the plane A is obtained by the following equations (5) and (6).
X=L×(b−a)/(a+b) (5)
Y=2×F×L/(a+b) (6)

As indicated by these Equations (5) and (6), the two-dimensional position (X, Y) of the detection target 4B on plane A can be obtained from physical fixed values F and L as well as positional information “a” of a real image and positional information “b” of a mapped image on the detection surface 26 of the two-dimensional light sensor 25.

As parameters for obtaining a Z-axial component of the detection target, the following variable is required.

<Variable>

e: Z-axial position of the detection target on the two-dimensional light sensor 25.

In FIG. 17B, Z=e×Y/F is given.

Thus, the Z-axial component of the detection target is obtained by the following Equation (7).
Z=e×Y/F=2×e×F×L/(a+b) (7)

As indicated in this Equation (7), a Z-axial component of a detection target can be obtained from the physical fixed values F and L, the positional information “a” of a real image and the positional information “b” of a mapped image on the detection surface 26 of the two-dimensional light sensor 25, and the positional information “e” of the detection target on the detection surface 26 of the two-dimensional light sensor 25.

Further, a three-dimensional position of the detection target 4B in the detection range 3A can be obtained from the above Equations (5), (6), and (7).

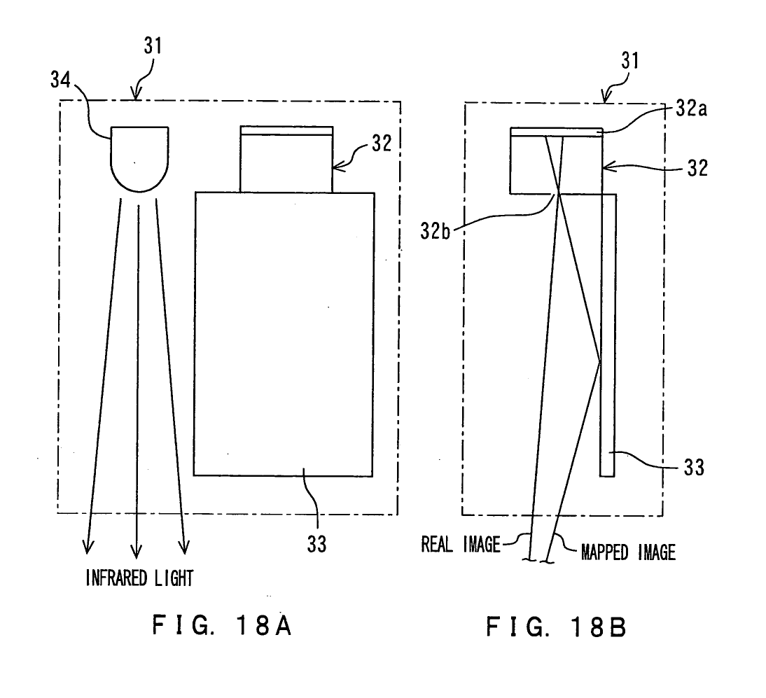

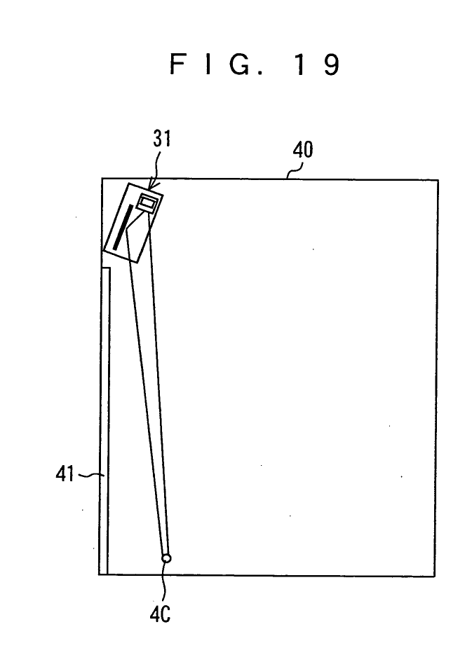

FIGS. 18A and 18B are explanatory diagrams each for showing an application of the fifth embodiment of the position-detecting device. FIG. 18A is a schematic view thereof and FIG. 18B is a schematic side view thereof. In FIGS. 18A and 18B, the position-detecting device is applied to monitoring of a door. A three-dimensional position detector 31 as a position-detecting device comprises a camera unit 32, a mirror 33, and an infrared-light emitting device 34.

The camera unit 32 comprises a two-dimensional light sensor 32a and a pinhole 32b for focusing light to this two-dimensional light sensor 32a. The mirror 33 has a planate reflecting surface and the two-dimensional light sensor 32a is made perpendicular to the mirror 33.

Here, an axis that is perpendicular to the mirror 33 and passes through the pinhole 32b is supposed to be an X-axis and a straight line that is perpendicular to the two-dimensional light sensor 32a and intersects with the X-axis on a mirror surface thereof, to be a Y-axis. Further, a straight line that is parallel to a plane including the two-dimensional light sensor 32a and a tangent line of the mirror surface and intersects with the X-axis on the mirror surface is supposed to be a Z-axis.

The infrared-light emitting device 34 is arranged in the proximity of the camera unit 32. This infrared-light emitting device 34 is constituted of, for example, a plurality of light-emitting elements, so that infrared light is emitted in sequence by turning its angle in the direction along an X-Y plane.

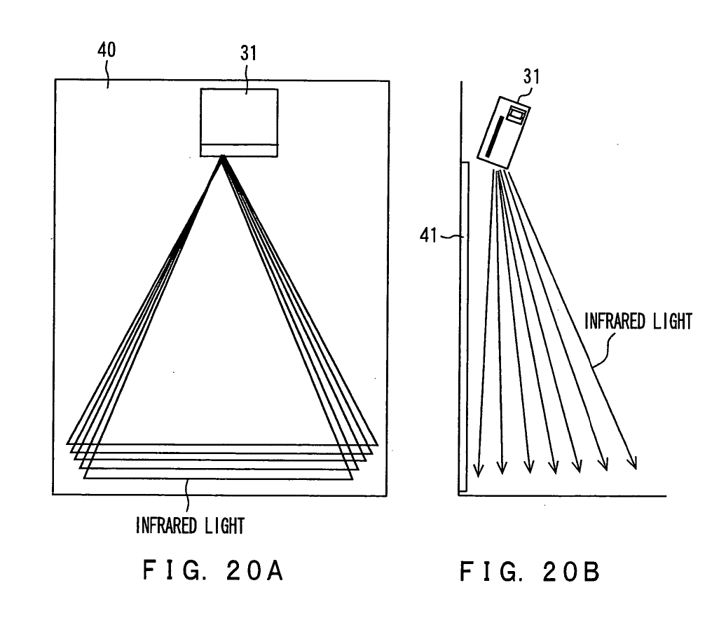

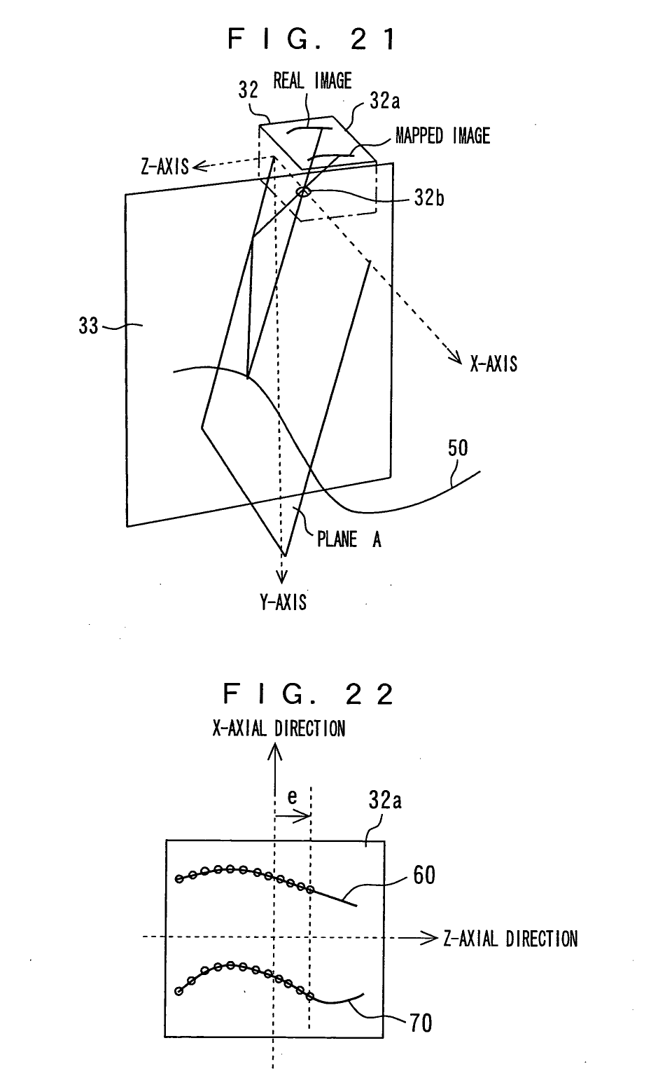

FIG. 19 is an explanatory diagram for showing an arrangement example of the three-dimensional position detector 31. The three-dimensional position detector 31 is arranged within, for example, an elevator 40 at a part upper a door 41 thereof. Then, when infrared light is emitted to a vicinity of the door 41, the detector 32 receives light reflected by a detection target 4C. FIGS. 20A and 20B are explanatory diagrams each for showing an example of an infrared light irradiation range. FIG. 20A is a plan view thereof and FIG. 20B is a side view thereof.

Infrared light from the infrared-light emitting device 34 is radiated within a certain range of angle as shown in FIG. 20A. This infrared light is specifically radiated in sequence by turning its angle along the X-Y plane as shown in FIG. 20B.

FIGS. 21 and 22 are explanatory diagrams each for showing a principle of measuring a three-dimensional position using a three-dimensional position detector. Since the infrared light is radiated in sequence by turning its direction along the direction along the X-Y plane, it is radiated in a plane from the three-dimensional position detector 31, so that light 50 reflected by a subject appears linear as shown in FIG. 21.

Then, a three-dimensional position of the subject is obtained by an intersection between a plane A that is perpendicular to the mirror 33 and passes through the pinhole 32b and the reflected linear infrared light 50. FIG. 22 shows a locus 60 of a real image of the subject and a locus 70 of a mapped image thereof on the two-dimensional light sensor 32a. Along the Z-axis of the two-dimensional light sensor 32, positional information on these real and mapped images is sampled using as a unit the variable “e” described in FIG. 17. Based on resultant data, X, Y coordinates can be calculated on the basis of the principle described in FIG. 17, thereby obtaining X-, Y-, and Z-coordinates of the reflected linear infrared light.

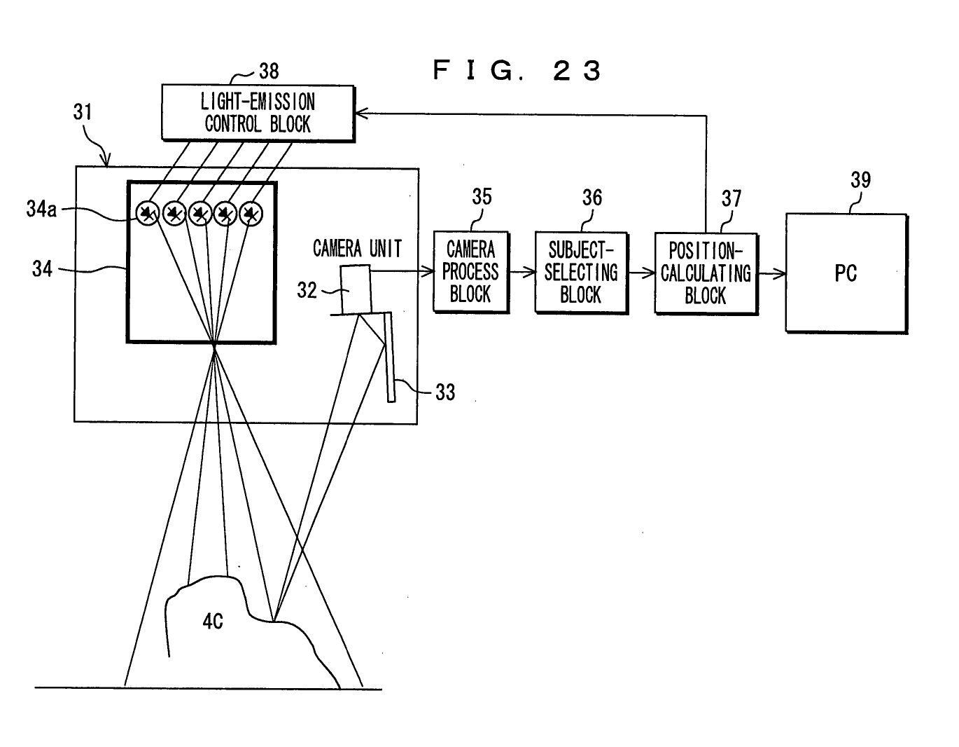

FIG. 23 is a block diagram for showing a configuration of a control system of a three-dimensional position detector. Such a position detector 31 comprises a camera process block 35, a subject-selecting block 36, a position-calculating block 37, and a light-emission control block 38. The camera process block 35 controls the two-dimensional light sensor 32a of the camera unit 32 and performs A/D conversion to output data of a picked up image of a subject to the subject-selecting block 36.

The subject-selecting block 36 selects two items of linear infrared light data concerning a real image and a mapped image of the subject from the picked-up subject image data output from the camera process block 35.

From the selected linear infrared light data, the position-calculating block 37 calculates a position of the linear infrared light based on the principle described in FIG. 16. The light-emission control block 38 repeatedly causes the plurality of light-emitting elements of the infrared light emitting device 34, for example, light-emitting diodes 34a to emit light in sequence so that the infrared light may be radiated repeatedly by turning its angle.

Then, from the positions of the linear infrared light calculated by the position-calculating block 37 and the information etc. of the light-emitting diodes 34a caused to emit by the light-emission control block 38, positional data of the linear infrared light of a portion of the subject is piled up. It is to be noted that the positional data of the subject is sent to, for example, a personal computer (PC) 39, where an application related to the positional data of the subject is executed.

While the foregoing specification has described preferred embodiment (s) of the present invention, one skilled in the art may make many modifications to the preferred embodiment without departing from the invention in its broader aspects. The appended claims therefore are intended to cover all such modifications as fall within the true scope and spirit of the invention.

1. A position-detecting device comprising:
a reflector; and
a detector for detecting positional information of a real image of a detection target and a mapped image of the detection target reflected by said reflector, said detector having a detection surface for picking up the real image and the mapped image of said detection target on said detection surface,
wherein coordinates of a position of said detection target are obtained from the positional information of said real image and the mapped image of said detection target on said detection surface.

2. The position-detecting device according to claim 1, wherein said detector is arranged with said detection surface being inclined with respect to a reflecting surface of the reflector.

3. The position-detecting device according to claim 1, wherein said detector is arranged with said detection surface being perpendicular to a reflecting surface of said reflector.

4. The position-detecting device according to claim 1, wherein said detector comprises a light sensor to detect a two-dimensional position of a detection target, said light sensor being a plurality of image pick-up elements arrayed at least in a row.

5. The position-detecting device according to claim 1, wherein said detector comprises a light sensor to detect a three-dimensional position of a detection target, said light sensor being a plurality of image pick-up elements arrayed two-dimensionally.

6. The position-detecting device according to claim 1, wherein said detector is arranged along one of sides of a display for displaying information and said reflector is arranged along at least one of sides that intersect with the side along which said detector is arranged.

7. The position-detecting device according to claim 6, wherein a light source is provided on a side of said display, said side being opposed to the side along which said detector is arranged.

8. The position-detecting device according to claim 6, comprising:
a light source on a side of said display, said side along which said detector is arranged; and
a reflecting structure for reflecting light radiated from said light source toward said detector.

9. The position-detecting device according to claim 7, wherein said display is of a light-receiving type and uses a light source for irradiating said display as said light source.

10. The position-detecting device according to claim 7,
wherein said display is of a self-emitting type and uses a portion of light emitted from said display as said light source.

11. The position-detecting device according to claim 6, further comprising:
optical-path changing device for changing a direction of light with which a detection target on said display is irradiated, toward said detector; and
moving device for retracting said optical-path changing device from a front side of said detector,
wherein said detector comprises a light sensor in which a plurality of image pick-up elements is arrayed two-dimensionally.
